(19) United States
(12) Patent Application Publication
(10) Pub. No.: US 2022/0093681 A1
(43) Pub. Date: Mar. 24, 2022

(54) FOLDABLE LOW POWER DISPLAYS

(71) Applicant: Intel Corporation, Santa Clara, CA (US)

(72) Inventors: Khaled Ahmed, San Jose, CA (US); Marshall Smith, Mesa, AZ (US)

(21) Appl. No.: 17/542,113

(22) Filed: Dec. 3, 2021

(51) Int. Cl. H01L 27/15; H01L 33/42; H01L 33/62; H01L 33/10; H01L 33/32; H01L 33/00; G09F 9/30

(52) U.S. Cl. CPC H01L 27/156; H01L 33/42; H01L 33/62; H01L 33/10; H01L 2933/0016; H01L 33/0075; G09F 9/301; H01L 2933/0066; H01L 33/32

(57) ABSTRACT

Methods and systems for creation of a flexible display panel, useable with a folding palm top or similar device, are disclosed. Embodiments include forming a micro-LED based display panel that uses a transparent flexible electrode. The transparent flexible electrode is fabricated from reduced graphene oxide and a wire mesh, to achieve a flexible electrode that is comparable to known Indium-Tin-Oxide electrodes in transparency and electrical characteristics, but is sufficiently flexible to support folding device usages. Other embodiments are described.

### TECHNICAL FIELD

Disclosed embodiments are directed to techniques for manufacturing foldable displays, and in particular to techniques for preparing foldable low power displays with flexible transparent electrodes.

### BACKGROUND

Electronic display panels, such as may be found in a computer monitor, device display, or flat-panel television, may be implemented using a number of different technologies. Micro LEDs are a promising technology that offers superior contrast and color while also offering relatively low power consumption, in comparison to existing display technologies. For example, white micro LEDs can be used to create a monochrome display panel. Increasingly, micro LEDs are available in pixel sizes that can produce light in the specific wavelengths needed to reproduce a color picture, e.g. red, green, and blue, allowing a flat panel color display to be created directly from the micro LEDs, with red, green, and blue micro LEDs forming sub-pixels for each display pixel. Low power displays manufactured using micro LEDs are particularly suited to mobile applications, where battery longevity is desirable but constrained by battery capacity, as the display of a mobile device is typically one of the largest power draws.

The background description provided herein is for the purpose of generally presenting the context of the disclosure. Unless otherwise indicated herein, the materials described in this section are not prior art to the claims in this application and are not admitted to be prior art by inclusion in this section.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional view that depicts an example arrangement of layers for fabricating a micro-LED based display that uses a flexible electrode, according to various embodiments.

FIG. 2 is a cross-sectional view of the flexible electrode layer of the example arrangement depicted in FIG. 1, according to various embodiments.

FIG. 3 is a chart illustrating the relation between optical transmission and effective resistance of different types of electrode layers, including the flexible electrode layer depicted in FIG. 2, according to various embodiments.

FIG. 4 is a cross-sectional view depicting the arrangement of layers of a completed display following detachment of the substrate depicted in FIG. 1, according to various embodiments.

FIG. 5 is a flowchart of the operations of an example method for creating a display panel with a flexible electrode, according to various embodiments.

FIG. 6 is a block diagram of an example computer that can be used to implement some or all of the components of a system that may be used in fabricating a display panel with a flexible electrode or performing some of the operations of the example method of FIG. 5, according to various embodiments.

FIG. 7 is a block diagram of a computer-readable storage medium that can be used to implement some of the components of the methods disclosed herein, according to various embodiments.

### DETAILED DESCRIPTION

Display panels are critical components in modern mobile electronic devices, such as smartphones, tablets, and laptop/notebook computers. The established form factor for smartphones, tablets, and similar such devices has typically been a rigid slab, with one side comprising a touchscreen. As such devices increase in size to accommodate larger-sized screens, they become increasingly unwieldly, particularly if a user desires to carry such a device in a pocket. To address this problem, manufacturers have begun producing various devices that are foldable, similar to flip phones that were prevalent prior to the advent of smart phones. However, the foldable form factor is not compatible with the typical rigid touchscreen found on smartphones and tablets, which will fracture if bent. One possible solution is to employ two display panels, one each located in one half of the device. However, such a solution results in an undesirable break or line across the center of the screen to accommodate the fold.

An alternative solution is to employ a flexible display panel, which can span the device halves and accommodate the nearly 180 degree bend imposed when the device is folded, while opening to present a seamless display comparable in size or larger than the displays found on devices with the traditional slab form factor. Currently, organic light emitting diode (OLED) technology is widely adopted for forming flexible display panels. However, OLED panels can suffer from undesirable effects such as screen burn-in if a static image is left on a screen for an extended period of time. Micro LEDs, in contrast, are more resistant to burn-in, have longer life, and can potentially offer a brightness and contrast that equals or exceeds OLED technology, potentially with greater energy efficiency.

To function, micro LEDs require electrodes in contact with each LED to pass current when lit. Micro LED panels may be fabricated as part of a “sandwich” structure. Gate driving circuitry is fabricated in a layer beneath the micro LEDs, and the micro LEDs are placed upon electrodes or contacts provided by the gate driving circuitry. To complete the circuit, a second electrode must be placed on top of the micro LEDs. As it overlays the portion of each micro LED that generates light, this second electrode must be substantially transparent to minimize attenuation of light from each micro LED.

Transparent electrodes are commonly fabricated from Indium Tin Oxide (ITO), which can create low-resistance yet optically transparent electrode layers. However, ITO has several drawbacks. First, ITO is increasingly expensive, as one of its constituent components is Indium, a rare metal that is typically extracted as a by-product of extracting various other types of ores or host metals. Second, ITO is fragile and lacks flexibility. These characteristics present a challenge to use in flexible displays. Employing ITO in a flexible display panel either requires depositing a relatively thin layer that poses high resistivity, resulting in greater power draw and/or decreased brightness, or depositing a thicker layer that is more prone to cracking as the display is repeatedly folded and unfolded, resulting in a high rate of display failure in a relatively short time period.

Disclosed embodiments address these shortcomings by providing an optically transparent yet flexible electrode that is fabricated from reduced graphene oxide and a metal mesh. Graphene, as a form of Carbon, is abundant and can be produced relatively cheaply. In disclosed embodiments, graphene is utilized by depositing graphene oxide, which is then at least partially reduced to graphene. When deposited in a sufficiently thin layer, reduced graphene oxide is flexible yet durable, optically transparent, and conductive. While reduced graphene oxide is less conductive than a comparably thick layer of ITO, its conductivity can be enhanced without significant loss of optical transparency by doping with select elements and/or overlaying a metal mesh of nanowires, which reduces resistance while maintaining flexibility. As a result, displays fabricated with a reduced graphene oxide and metal mesh electrode can be highly flexible yet provide relatively low power consumption, durability, and relatively long life.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

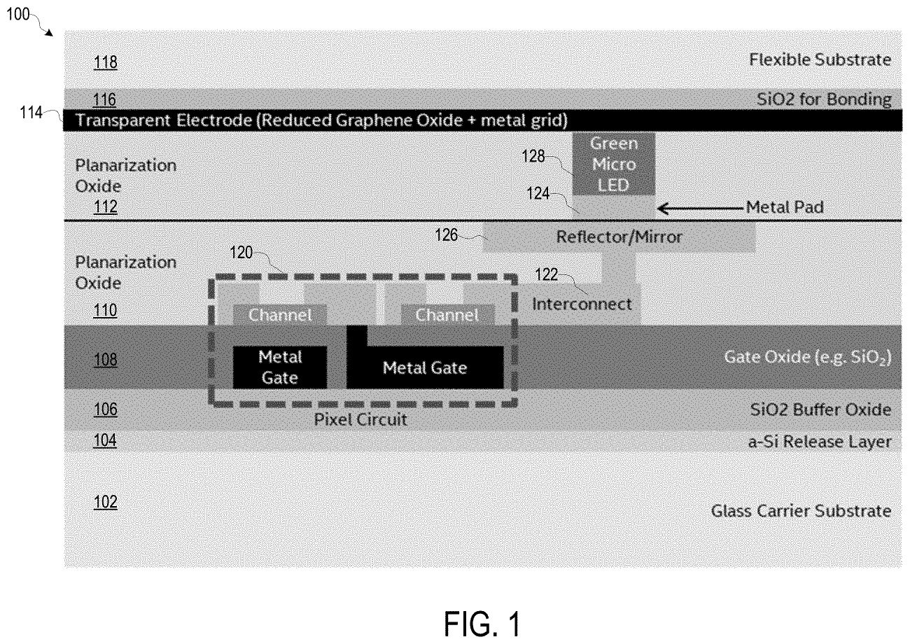

FIG. 1 illustrates an example arrangement 100 of layers on a substrate 102 for creating a micro-light emitting diode (micro-LED) display panel or assembly that utilizes a flexible electrode fabricated from reduced graphene oxide, according to some embodiments. Arrangement 100 includes substrate 102, a release layer 104, a buffer layer 106, a gate layer 108, two planarization layers 110 and 112, a transparent electrode layer 114, a bonding layer 116, and a flexible substrate 118. Within these layers are included various structures for providing display panel functionality, including driver circuitry 120 for controlling each micro-LED 128, which is connected to each micro-LED 128 via an interconnect 122 and metal pad 124. Further, a reflector or mirror 126 may be provided beneath and surrounding each micro-LED 128 to direct a greater proportion of useable light towards the flexible substrate 118, in the direction whereby a user would typically view the display panel.

Substrate 102, in embodiments, is a glass carrier that may be substantially rigid and can readily accept the release layer. Other wafers or substrates, which may be differently prepared, may be employed depending upon the process employed to create the display assembly. Following any necessary preparation of the substrate 102, a release layer 104 is applied or formed on the substrate 102. In the depicted embodiment, release layer 104 is formed from amorphous silicon, and is designed to allow the substrate 102 to be released from the remainder of the arrangement 100 via a laser ablation process. Accordingly, the substrate 102 may be fabricated from a material which is transparent or substantially transparent to the wavelength of laser light used in the ablation process, such as soda-lime glass, borosilicate glass, quartz (silicon dioxide) glass, sapphire glass, or another suitable transparent substrate.

The release layer 104 is a sacrificial layer which will be ablated to promote separation of the substrate 102 from the remaining layers of arrangement 100 display assembly is to be released from the substrate 102. When the release layer 104 is irradiated with a laser, the release layer 104 can vaporize as it absorbs energy from the laser and the vaporization gas pressure results in the separation of the display assembly from the substrate 102. In some embodiments, the laser used for ablation is an infrared laser with a wavelength of approximately 1950 nm, and may be directed to the side of the substrate opposite the side on which the remainder of the display assembly is formed, viz. the laser light passes through the substrate 102 to impact the release layer 104. As mentioned above, release layer 104 is formed from amorphous silicon in the depicted embodiment, and may be formed using low temperature atomic layer deposition (ALD). However, release layer 104, depending upon the implementation, may alternatively comprise titanium nitride, niobium nitride, tantalum nitride, another metal nitride, or any other material suitable for use in releasing the remainder of arrangement 100 from the substrate 102 via laser irradiation. In some embodiments, the thickness of the release layer 104 can be in the range of about 5-50 nm. In other embodiments, the thickness of the release layer 104 can be in the range of about 10-30 nm. In other embodiments, other materials may be used for the release layer 104 that are compatible with the other layers of arrangement 100.

Formed on top of the release layer 104 is a buffer layer 106, which may be formed from an oxide (e.g. silicon dioxide, SiO2). The buffer layer 106 may be selected to accommodate differences in crystalline structure between adjacent layers, viz. the amorphous silicon release layer 104 and the gate oxide layer 108. Alternatively or additionally, the buffer layer 106 may be selected for other desirable characteristics and functionality, such as thermal properties, structural support, support of release pressure during the ablation process, and protection of the driver circuitry 120 that may be formed immediately above the buffer layer 106.

A gate layer 108 is formed on the buffer layer 106 in the depicted embodiment. The gate layer 108 may be formed from silicon dioxide or another material suitable or appropriate to the type of circuitry to be implemented within the layer. The material of the gate layer 108 may further be selected with respect to the method used to create the components of the driver circuitry 120. As seen in FIG. 1, the gate layer 108 includes part of driver circuitry 120. In some embodiments, gate layer 108 may be masked and/or doped to form at least a part of the driver circuitry 120, such as one or more transistors implemented using thin-film transistor (TFT) technology. In other embodiments, the driver circuitry 120 may be separately formed using conventional or otherwise known semiconductor fabrication techniques, and then encased in the gate layer 108 material. In such embodiments, the material of gate layer 108 may be selected to ensure protection and/or proper functionality of the driver circuitry 120. In still other embodiments, the gate layer 108 may contribute to the operation of at least a portion of the driver circuitry 120. In yet other embodiments, some combination of the foregoing may be employed for fabrication, e.g. the gate layer 108 may be partially deposited, doped, and/or masked to create some of the components of driver circuitry 120, with the remainder of the gate layer 108 subsequently deposited following formation of the driver circuitry 120.

A first planarization layer 110 may be formed immediately above the gate layer 108, and may also include at least part of the components of the driver circuitry 120, as illustrated in the example embodiment of FIG. 1. These additional components may be formed similar to the process used to form the components of the driver circuitry 120 within the gate layer 108, such as photolithography techniques of doping and masking, formation of the driver circuitry 120 components first and then encasement with the first planarization layer 110, partial formation of the first planarization layer 110 to create the driver circuitry components 120, then formation of the remainder, etc. The first planarization layer 110 can comprise silicon dioxide or another suitable material that can act as an electrical insulator and/or be doped and processed using photolithography or another suitable process to create the various structures of driver circuitry 120. First planarization layer 110 may further include or encase one or more interconnects 122 associated with each micro-LED 128 to connect each micro-LED 128 with its respective portion of the driver circuitry 120, thereby allowing each micro-LED 128 to be controlled, e.g. switched on, switched off, or modulation of brightness. Each interconnect 122, as can be seen in the depicted embodiment, may pass through or connect to a reflector or mirror structure 126, and terminate to a metal pad 124 disposed or formed atop the first planarization layer 110. The interconnects 122 and reflector/mirror 126 may be formed as part of the first planarization layer 110, or formed first as a separate structure from the gate layer 108, with the first planarization layer 110 subsequently deposited as an insulating and/or structural support layer.

A second planarization layer 112 may be formed above the first planarization layer 110. The second planarization layer 112 can comprise silicon dioxide or another suitable material that can act as an electrical insulator and/or provide suitable structural support for the plurality of micro-LEDs. The second planarization layer 112 may be constructed of the same material as the first planarization layer 110, or of a different type of material, and may have the same or a different crystal lattice structure. The second planarization layer 112, in the depicted embodiment, may surround and encapsulate a plurality of micro-LEDs 128, each sitting atop and contacting a metal pad 124, that comprise the display panel. The second planarization layer 112 may encapsulate a plurality of metal pads 124, each of which provides one of the contacts to each of the micro-LEDs 128, connecting each micro-LED 128 to its respective driver circuitry.

As can be seen, the driver circuitry 120 is formed or constructed across the gate layer 108 and the planarization layer 110. While the depicted embodiment in FIG. 1 illustrates a plurality of metal gates and a corresponding plurality of channels, this should not be taken as limiting. The transistors may be MOSFETs and/or another suitable type of transistor technology. The circuit topology may be any suitable type that can suitably drive its connected micro-LED 128. Other embodiments may employ different types of technology for the driver circuitry 120, as may be appropriate for a given embodiment and type of micro-LED 128. The configuration, type, and number of transistors needed to drive a given micro-LED 128 may depend upon the nature of the micro-LED 128 as well as the requirements of a given device that may employ a display panel manufactured from arrangement 100. As mentioned above, the driver circuitry 120 connects to each micro-LED 128 via an interconnect 122, which passes through a reflector/mirror 126 to connect to a metal pad 124. The metal pad 124, as well as interconnect 122 in some embodiments, may be fabricated or formed from Copper, Aluminum, Gold, Silver, Platinum, or another suitable material. The metal pad 124 and interconnect 122 may be the same or different materials. In other embodiments, interconnect 122 may be formed as part of forming the driver circuitry 120, and so may be formed using conventional or known semiconductor fabrication techniques. The reflector/mirror 126 may be formed from Aluminum, Silver, Platinum, Nickel, an Aluminum-Silicon compound or another suitable material that effectively reflects the wavelength of light produced by its respective micro-LED 128. The reflector/mirror 126 may be deposited using a sputtering process, or another suitable fabrication process.

Each micro-LED 128 may be fabricated separately from the arrangement 100, on a separate wafer according to known processes, then transferred to the arrangement 100 and deposited or otherwise attached to its corresponding metal pad 124. Each micro-LED 128 may be fabricated to a suitable size and with a suitable material depending upon the desired output of a given micro-LED 128. Although the micro-LED 128 in the depicted arrangement 100 is configured to emit green light, it should be understood that a display panel may have a plurality of micro-LEDs 128, each of which may emit one of a plurality of different wavelengths. The selection of wavelengths in a given embodiment may depend upon the intended use of the resulting display panel. For example, in an embodiment intended for use in a palm top or similar foldable smart device or mobile device, the display panel may include micro-LEDs 128 that emit one of red, green, or blue wavelengths, to provide a full-color display panel. Each micro-LED 128 may be fabricated from gallium nitride, indium gallium nitride, or another suitable material, selected with consideration to the desired wavelength to be output by the micro-LED 128. Alternatively, each micro-LED 128 may be fabricated in situ in or on the first and second planarization layers 110 and 112. The second planarization layer 112 may be deposited following transfer of the plurality of micro-LEDs 128, to encapsulate and provide structural support to the micro-LEDs 128.

Each of the first and second planarization layers 110, 112 may be deposited using a suitable process such as plasma enhanced chemical vapor deposition (PECVD), or another suitable process. Each of the layers may further be planarized using a planarization process such as chemical-mechanical polish (CMP), or another suitable planarization process, which may be employed to create a substantially uniform height of the layers.

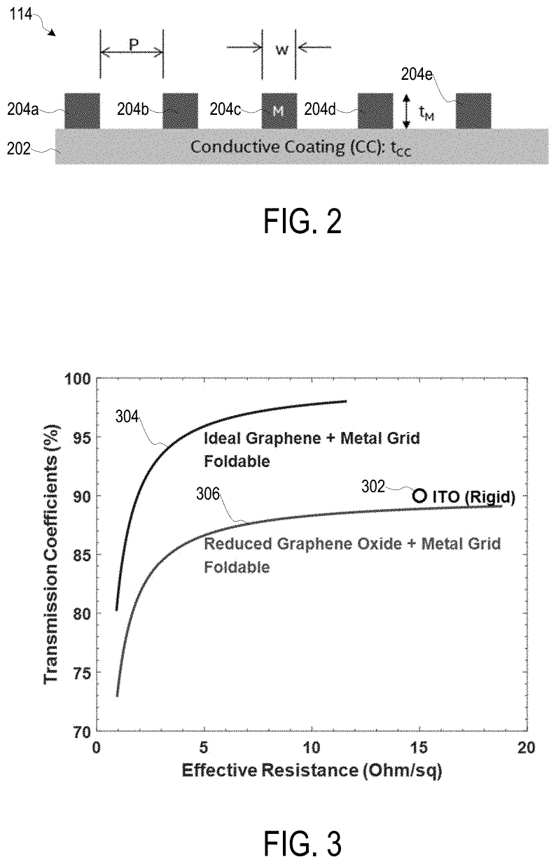

Following depositing of the micro-LEDs 128 and formation of the second planarization layer 112, and any necessary processing, the flexible transparent electrode layer 114 is deposited, which comprises a reduced graphene oxide and a metal grid comprised of nanowires. The formation and structure of the transparent electrode layer 114 will be discussed in greater detail below with reference to FIGS. 2 and 3.

It should be appreciated that the position of “top” or “topmost” in reference to the first planarization layer 110 and second planarization layer 112 is made with reference to the substrate 102 as the “bottom” layer or reference plane, and should not be understood as suggesting any particular orientation of the wafer during processing. In other terms, the topmost layer of the planarization layers 110, 112 is that layer that is most proximate to the transparent electrode layer 114.

Once the flexible transparent electrode layer 114 is formed, a bonding layer 116 is formed atop the electrode layer 114. In embodiments, the bonding layer 116 is comprised of Silicon Dioxide, or another suitable material. A flexible substrate 118 is then formed on the bonding layer 116. The flexible substrate 118 is selected to facilitate flexibility of any display panel that is ultimately fabricated from the arrangement 100, is optically transparent to allow light from the micro-LEDs 128 to pass through to a viewer, and acts to protect the underlying structures of the display panel. The flexible substrate 118 may be a thin glass substrate or a plastic substrate. Substrates formed of polyethylene terephthalate (PET), polycarbonate (PC), polyimide (PI), polyethylene naphthalate (PEN), polystyrene (PS), and the like may be used as the transparent flexible substrate 118.

In some embodiments, the bonding layer 116 and transparent flexible substrate 118 may be formed directly on the arrangement 100. In other embodiments, the transparent flexible substrate 118 may be formed separately, and then attached to the arrangement 100. One possible process for such a separate formation begins with coating a second glass wafer or substrate with a release layer, such as the amorphous Silicon release layer, using a suitable process such as ALD. Next, a transparent flexible film that will comprise flexible substrate 118 is formed onto the release layer, and a bonding layer, which may comprise Silicon Dioxide (SiO2), is formed on the flexible substrate 118. The flexible substrate 118 is transferred and adhered to the arrangement 100 by joining the bonding layer 116 formed on the transparent electrode layer 114 to the bonding layer formed on the flexible substrate 118, such as using SiO2 to SiO2 bonding. The second glass wafer is then detached from the arrangement 100 using laser ablation, leaving the transparent flexible substrate 118 attached to the arrangement 100.

Following formation of the arrangement 100, the arrangement 100 may be cut into the desired size(s) to form one or more display panels, and then laser ablation may be used to remove the carrier substrate 102 and, if not previously removed and if necessary, any substrate used to adhere the flexible substrate 118 to the arrangement 100.

Turning to FIG. 2, the configuration of the example transparent electrode layer 114 is depicted. The transparent electrode layer 114 is comprised of two sub-layers: a coating layer 202 of a conductive coating, and a wire mesh layer 204, indicated in cross section by wires 204a, 204b, 204c, 204d, and 204e. The coating layer 202 is comprised of reduced graphene oxide. To form the reduced graphene oxide, graphene oxide may be deposited or formed on a layer such as second planarization layer 112, using a suitable technique, such as by dispersal into a solution, allowing formation of a thin layer. This may result in a relatively even layer of graphene oxide that blankets over and contacts all micro-LEDs. The graphene oxide is a relatively poor conductor, so the graphene oxide is at least partially reduced to yield at least a proportion of graphene. Any reducing agent that is commonly used in the art may be used as the reducing agent without limitation, and examples of the reducing agent are NaBH4, N2H2, LiAlH4, TBAB, ethylene glycol, polyethylene glycol and sodium (Na). The extent to which the graphene oxide may be reduced depends upon the nature of the other layers of arrangement 100. Because the reduction process typically requires relatively high temperatures to achieve full or nearly full reduction to pure graphene, which may damage or otherwise be detrimental to the remaining layers of arrangement 100, the reduction of the graphene oxide to graphene is only partial, in embodiments. Further, the reduced graphene oxide may be doped to improve its electrical properties using an organic and/or inorganic dopant. The reduced graphene oxide, in embodiments, is doped with Nitrogen and/or Sulfur. Example doping sources could include HCl, H2PO4, H2S to yield Sulfur, or Ammonia or Hydrazine to yield Nitrogen. A plasma process may be used for reduction and/or doping. In some embodiments, the plasma process may simultaneously effect both reduction of the graphene oxide as well as doping.

Following formation of the conductive coating layer 202, a wire mesh layer 204 is overlaid upon the coating layer 202 to improve the electrical properties and reduce the resistance of the flexible transparent electrode layer 114. As the resistance of the electrode layer 114 is decreased, the overall power efficiency of the display panel will increase, as less energy is lost due to resistance. The wire mesh layer 204 is, in the depicted embodiment, primarily a grid or mesh of nanowires, and when in contact with the coating layer 202 provides a lower resistance path for electricity over the coating layer 202. The wire mesh layer 204 may be fabricated from Aluminum, Copper, Platinum, Gold, or another suitable metal. The selection of metal may depend upon the cost imposed in fabrication vs. the positive effect a particular metal may have on the electrical properties of the transparent electrode layer 114. In some embodiments, the wire mesh layer 204 is a grid of wires, forming squares similar to a window screen. However, depending upon the layout of the various micro-LEDs 128, the grid may form different shapes, e.g. triangles, hexagons, polygons, or other suitable shapes. By employing nanowires and positioning the mesh layer 204 so that the wires do not substantially overlay or cover any of the micro-LEDs 128, optical transparency of the flexible transparent electrode layer 114 may be maintained.

The sheet resistance, expressed in Ohms per square, and the transmission coefficient, a percentage of light generated by a given micro-LED that is actually transmitted from the display panel, can be computed for a given electrode layer 114 with a wire mesh layer 204, with the following equations:

$${R}_{SH} \approx \frac{( \frac{{ρ}_{M}}{{t}_{M}} \times \frac{w}{p - w} + \frac{{ρ}_{CC}}{{t}_{CC}} )}{1 + \frac{{w}^{2}}{( p - w ) p} + \frac{w}{p} ( \frac{{ρ}_{CC}}{{ρ}_{M}} ) ( \frac{{t}_{M}}{{t}_{CC}} )}$$

$$T = {T}_{CC} \times {( 1 - \frac{w}{p} )}^{2}$$

In the foregoing equations, R_{SH} is the sheet resistance in the top equation, and T is the transmission coefficient. With respect to the mesh, p is the spacing between the nanowires and w is the width of each of the nanowires of the wire mesh layer 204, as indicated in FIG. 2. The variables ρ_{M} and ρ_{CC} are the sheet resistivities of the wire mesh layer 204 and the coating layer 202, respectively. Likewise, t_{M} and t_{CC} are the thicknesses of the wire mesh layer 204 and the coating layer 202, respectively, and as indicated in FIG. 2. Finally, T_{CC} is the transmission coefficient of the coating layer 202. It should be understood that the foregoing equations assume a square grid pattern for the electrode with consistent spacing between nanowires. These equations may need to be modified where the wire mesh layer 204 is implemented using a non-square grid pattern.

FIG. 3 illustrates the effective resistance of both prior art films 302 of Indium Tin Oxide (ITO), idealized electrodes 304 of pure graphene and a metal grid, and electrodes 306 comprised of at least partially reduced graphene oxide and a metal grid, as disclosed herein. The foregoing equations may be used to derive the curves of the electrodes formed from a conductive coating and wire mesh. The effective resistance is illustrated as the x-axis, expressed as Ohms per square, and is plotted relative to the transmission coefficient, illustrated as the y-axis. As can be seen, an idealized electrode 304 of pure graphene yields the best optical transmission characteristics relative to effective resistance, approaching roughly 97-98% transmission coefficient with a corresponding effective resistance of roughly 10 Ohms per square. In contrast, an electrode 306, per the disclosed embodiments, provides roughly 88% transmission coefficient at an effective resistance of 10 Ohms per square. However, and for comparison, a film 302 of ITO has a transmission coefficient of around 90%, but at greater than 15 Ohms per square. Thus, the disclosed embodiments of a flexible electrode comprised of a reduced graphene oxide and metal grid yield transmission coefficients comparable to known, brittle, ITO films but potentially with equal or lower effective resistance. Furthermore, it should be understood that additional reductive processing could move the curve of electrodes 306 up towards the curve of the idealized electrode 304, provided that such processing would not detrimentally affect the other layers of an arrangement 100, such as the glass substrate. In such embodiments, a transparent flexible electrode according to the embodiments disclosed herein, such as transparent electrode 114, could exceed the performance of existing ITO films.

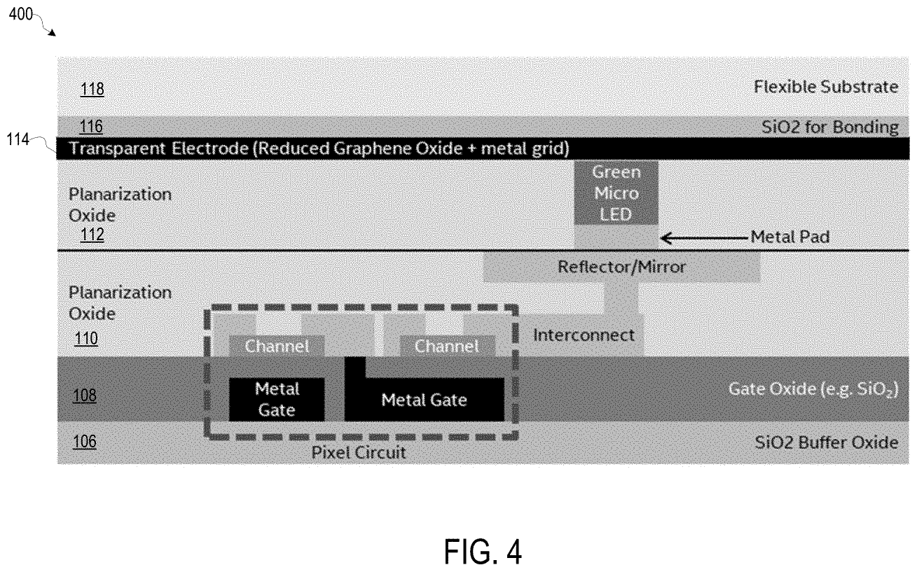

FIG. 4 illustrates a final arrangement 400 of layers following release of the substrate 102 and any substrate that may be used to adhere the flexible substrate 118 to the arrangement 400. Arrangement 400 is the expected configuration of a possible embodiment of a display panel created according to the disclosed embodiments. The various layers retain the call-outs from arrangement 100, and the reader is directed to the foregoing discussion of the various layers with respect to FIG. 1 for more details. Arrangement 400 may be further processed to form a display panel by providing appropriate connections to external circuitry to the driver circuitry and the transparent electrode 114, which in turn may be incorporated into a device such as a monitor, smart device, smart watch, mobile device, palm top device, laptop, television, or another device that can benefit from the flexible panel of arrangement 400. By using a flexible substrate 118 and flexible transparent electrode 114, arrangement 400 enables a display panel that can not only be used in a foldable or folding display, but is also energy efficient.

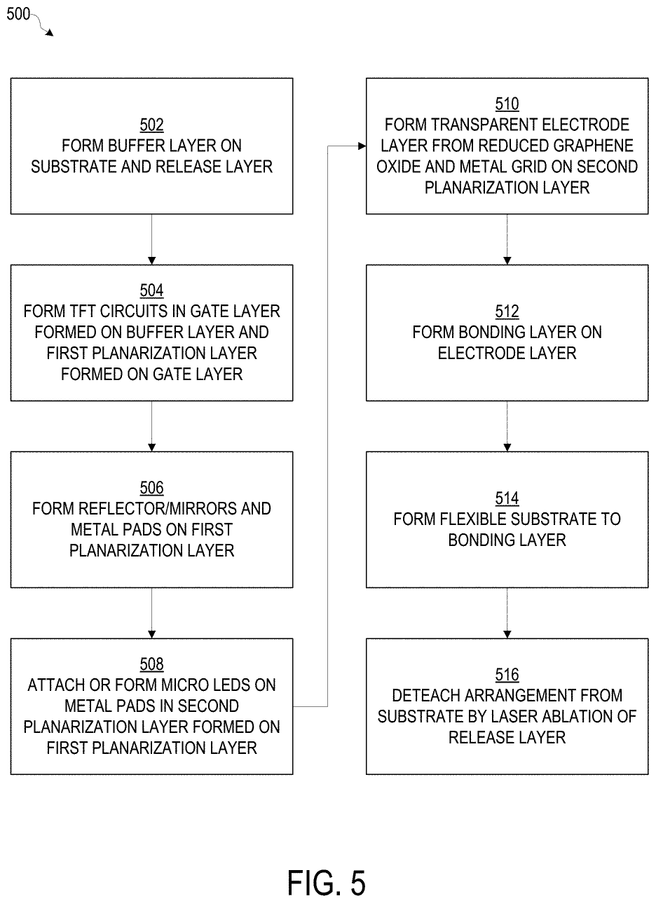

FIG. 5 is a flowchart of the operation of an example method 500 for creating a foldable display with a flexible transparent electrode, such as arrangement 400, according to a possible embodiment. The operations of method 500 may be carried out in whole or in part, and in order or out of order as the operations may permit. Additional operations may be added in some embodiments, and some operation may be omitted in some embodiments. For specifics of some of these operations, the reader is referred to the description above in connection with FIG. 1.

In operation 502, a buffer layer is formed atop a rigid substrate, upon which a release layer has been applied or formed. As discussed above, the release layer may comprise amorphous silicon or another material suitable for a laser ablation process to effect release of the substrate in a subsequent operation.

In operation 504, TFT circuits that comprise the diver circuitry for the micro-LEDs are formed. The TFT circuits are formed within or as part of a gate layer that is formed on the buffer layer, and a first planarization layer that is formed on the gate layer. As discussed above, in some embodiments, the TFT circuits may be formed from the gate and first planarization layers following formation of the layers, or may be formed prior to deposition or forming of the gate and/or first planarization layer, with the gate and/or first planarization layers formed following completion of layer formation. In other embodiments, one layer may be formed and then circuitry components formed from the layer, with other components formed first and their layers formed after component formation, e.g. components may be formed and then the gate and first planarization layers formed, with the remaining components then formed within the first planarization layer after the first planarization layer is formed.

In operation 506, reflectors or mirrors may be formed surrounding interconnects in the first planarization layer, with the reflectors/mirrors positioned so that they will underlie each micro-LED. Following formation of the reflectors/mirrors, metal pads may be formed atop the first planarization layer where each micro-LED will be positioned, to form one of the electrical contacts to each micro-LED. In some embodiments, the reflector/mirror and metal pad may be formed as a single structure, where the metal for the metal pad can also act as a suitable mirror or reflector.

In operation 508, a plurality of micro-LEDs are transferred to the metal pads formed on the first planarization layer, and a second planarization layer is then formed around the plurality of micro-LEDs to encapsulate the micro-LEDs for protection and structural support. Alternatively, in some embodiments the micro-LEDs may be formed or fabricated directly on the first planarization layer and/or from the second planarization layer.

In operation 510, a flexible transparent electrode layer is formed. As discussed above with respect to FIG. 2, the transparent electrode layer, such as electrode layer 114 in embodiments, is formed by first depositing a layer of graphene oxide on the second planarization layer. This layer of graphene oxide is then at least partially reduced to graphene, and doped, to improve its electrical characteristics. Following formation of the reduced graphene oxide layer, a metal wire mesh is overlaid upon the reduced graphene oxide layer to further improve the resistance characteristics of the electrode layer.

Next, in operation 512, a bonding layer is formed on top of the electrode layer, and in operation 514, a flexible substrate is formed or adhered to the bonding layer. As discussed above with respect to FIG. 1, in some embodiments, a bonding layer is formed on the electrode layer, the flexible substrate is formed onto a separate carrier substrate and a bonding layer formed onto the flexible substrate, then the two bonding layers are adhered and the carrier substrate detached, resulting in the formed bonding layer and flexible substrate attached to the arrangement.

Finally, in operation 516, the arrangement is released from the glass substrate, such as by using laser ablation to vaporize the release layer. The resulting arrangement may then be further processed into a display panel. In some embodiments, the arrangement may be cut to a desired dimension for a display panel prior to operation 516.

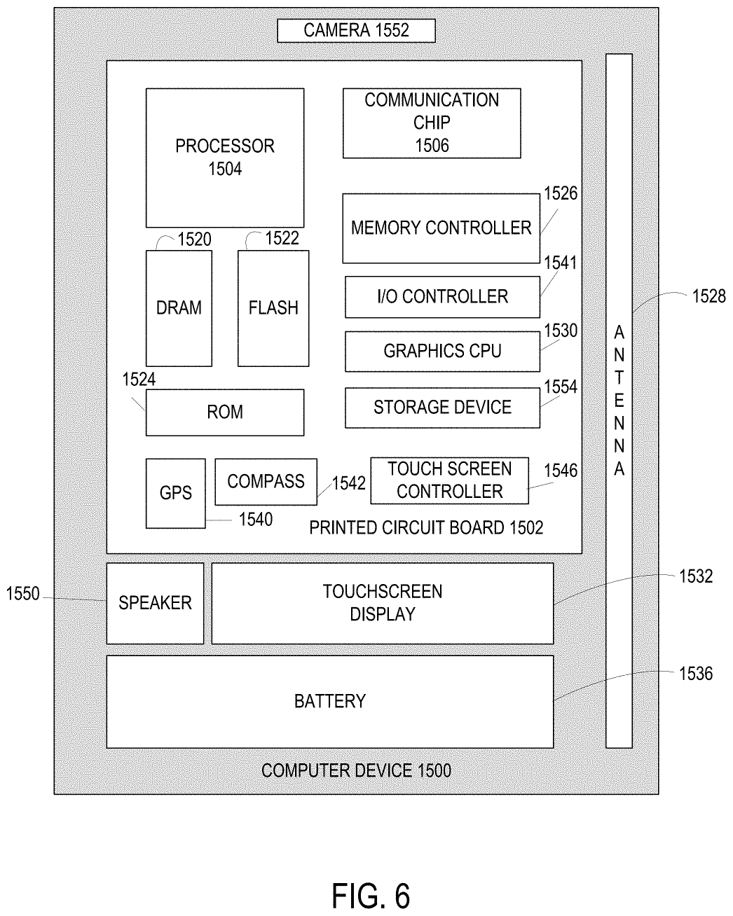

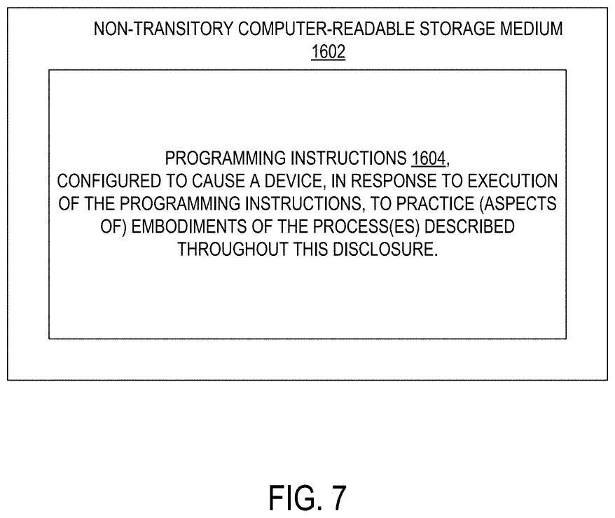

Method 500 may be carried out by an automated process or system, which may be performed by one or more computer devices 1500, discussed below with respect to FIG. 6, that may be running computer readable software, discussed below with respect to FIG. 7. Furthermore, it should be understood that while the foregoing discusses a semiconductor structure in singular, the foregoing processes may be used on a wafer in the simultaneous fabrication of multiple semiconductors, depending upon the particulars of a given implementation.

FIG. 6 illustrates an example computer device 1500 that may be employed by the apparatuses and/or methods described herein, in accordance with various embodiments. As shown, computer device 1500 may include a number of components, such as one or more processor(s) 1504 (one shown) and at least one communication chip 1506. In various embodiments, one or more processor(s) 1504 each may include one or more processor cores. In various embodiments, the one or more processor(s) 1504 may include hardware accelerators to complement the one or more processor cores. In various embodiments, the at least one communication chip 1506 may be physically and electrically coupled to the one or more processor(s) 1504. In further implementations, the communication chip 1506 may be part of the one or more processor(s) 1504. In various embodiments, computer device 1500 may include printed circuit board (PCB) 1502. For these embodiments, the one or more processor(s) 1504 and communication chip 1506 may be disposed thereon. In alternate embodiments, the various components may be coupled without the employment of PCB 1502.

Depending on its applications, computer device 1500 may include other components that may be physically and electrically coupled to the PCB 1502. These other components may include, but are not limited to, memory controller 1526, volatile memory (e.g., dynamic random access memory (DRAM) 1520), non-volatile memory such as read only memory (ROM) 1524, flash memory 1522, storage device 1554 (e.g., a hard-disk drive (HDD)), an I/O controller 1541, a digital signal processor (not shown), a crypto processor (not shown), a graphics processor 1530, one or more antennae 1528, a display, a touch screen display 1532, a touch screen controller 1546, a battery 1536, an audio codec (not shown), a video codec (not shown), a global positioning system (GPS) device 1540, a compass 1542, an accelerometer (not shown), a gyroscope (not shown), a speaker 1550, a camera 1552, and a mass storage device (such as hard disk drive, a solid state drive, compact disk (CD), digital versatile disk (DVD)) (not shown), and so forth.

In some embodiments, the one or more processor(s) 1504, flash memory 1522, and/or storage device 1554 may include associated firmware (not shown) storing programming instructions configured to enable computer device 1500, in response to execution of the programming instructions by one or more processor(s) 1504, to practice all or selected aspects of the method 500 or the various process flows described herein. In various embodiments, these aspects may additionally or alternatively be implemented using hardware separate from the one or more processor(s) 1504, flash memory 1522, or storage device 1554.

The communication chips 1506 may enable wired and/or wireless communications for the transfer of data to and from the computer device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to IEEE 802.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 1500 may include a plurality of communication chips 1506. For instance, a first communication chip 1506 may be dedicated to shorter range wireless communications such as Wi-Fi and Bluetooth, and a second communication chip 1506 may be dedicated to longer range wireless communications such as GPS, EDGE, GPRS, CDMA, WiMAX, LTE, Ev-DO, and others.

In various implementations, the computer device 1500 may be a laptop, a netbook, a notebook, an ultrabook, a smartphone, a computer tablet, a personal digital assistant (PDA), a desktop computer, smart glasses, or a server. In further implementations, the computer device 1500 may be any other electronic device that processes data.

As will be appreciated by one skilled in the art, the present disclosure may be embodied as methods or computer program products. Accordingly, the present disclosure, in addition to being embodied in hardware as earlier described, may take the form of an entirely software embodiment (including firmware, resident software, micro-code, etc.) or an embodiment combining software and hardware aspects that may all generally be referred to as a “circuit,” “module” or “system.” Furthermore, the present disclosure may take the form of a computer program product embodied in any tangible or non-transitory medium of expression having computer-usable program code embodied in the medium. FIG. 7 illustrates an example computer-readable non-transitory storage medium that may be suitable for use to store instructions that cause an apparatus, in response to execution of the instructions by the apparatus, to practice selected aspects of the present disclosure. As shown, non-transitory computer-readable storage medium 1602 may include a number of programming instructions 1604. Programming instructions 1604 may be configured to enable a device, e.g., computer 1500, in response to execution of the programming instructions, to implement (aspects of) the method 500 or the various process flows described above. In alternate embodiments, programming instructions 1604 may be disposed on multiple computer-readable non-transitory storage media 1602 instead. In still other embodiments, programming instructions 1604 may be disposed on computer-readable transitory storage media 1602, such as, signals.

Any combination of one or more computer usable or computer readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to wireless, wireline, optical fiber cable, RF, etc.

Computer program code for carrying out operations of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

### EXAMPLES

The following examples pertain to further embodiments:

Example 1 is an apparatus, comprising a buffer layer; a gate layer formed on the buffer layer; one or more planarization layers formed on the gate layer; a plurality of micro light-emitting diodes (LEDs) formed within the one or more planarization layers; and a flexible transparent electrode layer formed on the one of the one or more planarization layers that is most distal from the gate layer, the electrode layer comprised of graphene.

Example 2 includes the subject matter of example 1, or some other example herein, further comprising a rigid glass substrate upon which is formed a release layer, and the buffer layer is formed upon the release layer.

Example 3 includes the subject matter of example 2, or some other example herein, wherein the release layer is comprised of amorphous silicon.

Example 4 includes the subject matter of any of examples 1-3, or some other example herein, wherein the electrode layer is further comprised of a metal grid formed on top of the graphene.

Example 5 includes the subject matter of any of examples 1-4, or some other example herein, wherein the graphene of the electrode layer is doped with an organic or inorganic dopant that improves its conductivity.

Example 6 includes the subject matter of example 5, or some other example herein, wherein the dopant is at least partially comprised of Nitrogen or Sulfur.

Example 7 includes the subject matter of any of examples 1-6, or some other example herein, wherein the graphene of the electrode layer is further at least partially comprised of Carbon and Oxygen.

Example 8 includes the subject matter of any of examples 1-7, or some other example herein, wherein a plurality of thin-film transistors (TFTs) are formed on the buffer layer.

Example 9 includes the subject matter of any of examples 1-8, or some other example herein, further comprising a flexible recipient substrate adhered to a contact layer, the contact layer formed on the electrode layer.

Example 10 includes the subject matter of any of examples 1-9, or some other example herein, wherein the micro-LED is formed from a compound that comprises Gallium and Nitrogen.

Example 11 includes the subject matter of any of examples 1-10, or some other example herein, wherein the one or more planarization layers are comprised of Silicon and Oxygen.

Example 12 is a method, comprising forming, upon a rigid substrate, a release layer; forming, upon the release layer, a flexible display assembly, wherein forming the flexible display assembly comprises forming, upon the release layer, a buffer layer; forming, upon the buffer layer, a plurality of thin-film transistors (TFTs); forming, upon the plurality of TFTs, a plurality of metal pads; forming, upon the plurality of metal pads, a corresponding plurality of micro-light emitting diodes (micro LEDs); forming, upon the micro LEDs, a transparent flexible cathode layer that is at least partially comprised of graphene; forming, upon the flexible cathode layer, a bonding layer; and forming, upon the bonding layer, a flexible substrate; and releasing the flexible display assembly from the rigid substrate.

Example 13 includes the subject matter of example 12, or some other example herein, wherein releasing the flexible display assembly from the rigid substrate comprises exposing the release layer to a laser to cause it to ablate.

Example 14 includes the subject matter of example 12 or 13, or some other example herein, wherein forming the transparent flexible cathode layer further comprises forming, upon the micro LEDs, a first layer comprised of graphene and oxygen; reducing the first layer at least partially to remove some of the oxygen; doping the first layer with Nitrogen or Sulfur; and forming, upon the first layer, a second layer comprised of a metal mesh.

Example 15 includes the subject matter of example 14, or some other example herein, wherein reducing the first layer comprises reducing the first layer with a reducing agent comprised of one or more of Sodium, Boron, Hydrogen, Nitrogen, Lithium, or Aluminum.

Example 16 includes the subject matter of any of examples 12-15, or some other example herein, wherein forming the plurality of TFTs comprises forming, upon the buffer layer, a gate layer; forming upon the gate layer, a planarization layer; forming the plurality of TFTs within the gate layer and planarization layer; and forming the plurality of metal pads on the planarization layer.

Example 17 includes the subject matter of example 16, or some other example herein, further comprising forming, on the planarization layer, a plurality of reflectors, and wherein forming the plurality of metal pads on the planarization layer comprises forming the plurality of metal pads on the plurality of reflectors.

Example 18 includes the subject matter of any of examples 12-17, or some other example herein, wherein forming the plurality of micro LEDs comprises transferring the plurality of micro LEDs that are pre-formed from a donor substrate to the plurality of metal pads; and forming, around the plurality of micro LEDs, a planarization layer.

Example 19 includes the subject matter of any of examples 12-18, or some other example herein, wherein the bonding layer is a first bonding layer, and forming the flexible substrate comprises forming, on the flexible substrate, a second bonding layer; and joining the first bonding layer to the second bonding layer.

Example 20 is a system, comprising a buffer layer; a gate layer formed on the buffer layer and a first planarization layer formed on the gate layer, the gate layer and first planarization layer comprising a plurality of circuits; a second planarization layer comprising a plurality of micro-light emitting diodes (LEDs); a transparent flexible electrode layer formed on the second planarization layer; a bonding layer formed on the flexible electrode layer; and a flexible substrate formed on the bonding layer.

Example 21 includes the subject matter of example 20, or some other example herein, wherein the plurality of circuits comprise a plurality of thin-film transistors (TFTs).

Example 22 includes the subject matter of example 20 or 21, or some other example herein, wherein the transparent flexible electrode layer comprises partially reduced graphene and a metal mesh.

Example 23 includes the subject matter of example 22, or some other example herein, wherein the metal mesh is comprised of one or more of Aluminum, Copper, Platinum, or Gold.

Example 24 includes the subject matter of any of examples 20-23, or some other example herein, wherein the system comprises a foldable display.

Example 25 includes the subject matter of example 24, or some other example herein, wherein the foldable display is part of a foldable palm-top device.

What is claimed is:

1. An apparatus, comprising:
a buffer layer;
a gate layer formed on the buffer layer;
one or more planarization layers formed on the gate layer;
a plurality of micro light-emitting diodes (LEDs) formed within the one or more planarization layers; and
a flexible transparent electrode layer formed on the one of the one or more planarization layers that is most distal from the gate layer, the electrode layer comprised of graphene.

2. The apparatus of claim 1, further comprising a rigid glass substrate upon which is formed a release layer, and the buffer layer is formed upon the release layer.

3. The apparatus of claim 2, wherein the release layer is comprised of amorphous silicon.

4. The apparatus of claim 1, wherein the electrode layer is further comprised of a metal grid formed on top of the graphene.

5. The apparatus of claim 1, wherein the graphene of the electrode layer is doped with an organic or inorganic dopant that improves its conductivity.

6. The apparatus of claim 5, wherein the dopant is at least partially comprised of Nitrogen or Sulfur.

7. The apparatus of claim 1, wherein the graphene of the electrode layer is further at least partially comprised of Carbon and Oxygen.

8. The apparatus of claim 1, wherein a plurality of thin-film transistors (TFTs) are formed on the buffer layer.

9. The apparatus of claim 8, further comprising a flexible recipient substrate adhered to a contact layer, the contact layer formed on the electrode layer.

10. The apparatus of claim 1, wherein the micro-LED is formed from a compound that comprises Gallium and Nitrogen.

11. The apparatus of claim 1, wherein the one or more planarization layers are comprised of Silicon and Oxygen.

12. A method, comprising:
forming, upon a rigid substrate, a release layer;
forming, upon the release layer, a flexible display assembly, wherein forming the flexible display assembly comprises:
forming, upon the release layer, a buffer layer;
forming, upon the buffer layer, a plurality of thin-film transistors (TFTs);
forming, upon the plurality of TFTs, a plurality of metal pads;
forming, upon the plurality of metal pads, a corresponding plurality of micro-light emitting diodes (micro LEDs);
forming, upon the micro LEDs, a transparent flexible cathode layer that is at least partially comprised of graphene;
forming, upon the flexible cathode layer, a bonding layer; and
forming, upon the bonding layer, a flexible substrate; and
releasing the flexible display assembly from the rigid substrate.

13. The method of claim 12, wherein releasing the flexible display assembly from the rigid substrate comprises exposing the release layer to a laser to cause it to ablate.

14. The method of claim 12, wherein forming the transparent flexible cathode layer further comprises:
forming, upon the micro LEDs, a first layer comprised of graphene and oxygen;
reducing the first layer at least partially to remove some of the oxygen;
doping the first layer with Nitrogen or Sulfur; and
forming, upon the first layer, a second layer comprised of a metal mesh.

15. The method of claim 14, wherein reducing the first layer comprises reducing the first layer with a reducing agent comprised of one or more of Sodium, Boron, Hydrogen, Nitrogen, Lithium, or Aluminum.

16. The method of claim 12, wherein forming the plurality of TFTs comprises:
forming, upon the buffer layer, a gate layer;
forming upon the gate layer, a planarization layer;
forming the plurality of TFTs within the gate layer and planarization layer; and
forming the plurality of metal pads on the planarization layer.

17. The method of claim 16, further comprising forming, on the planarization layer, a plurality of reflectors, and wherein forming the plurality of metal pads on the planarization layer comprises forming the plurality of metal pads on the plurality of reflectors.

18. The method of claim 12, wherein forming the plurality of micro LEDs comprises transferring the plurality of micro LEDs that are pre-formed from a donor substrate to the plurality of metal pads; and forming, around the plurality of micro LEDs, a planarization layer.

19. The method of claim 12, wherein the bonding layer is a first bonding layer, and forming the flexible substrate comprises forming, on the flexible substrate, a second bonding layer; and joining the first bonding layer to the second bonding layer.

20. A system, comprising:
a buffer layer;
a gate layer formed on the buffer layer and a first planarization layer formed on the gate layer, the gate layer and first planarization layer comprising a plurality of circuits;
a second planarization layer comprising a plurality of micro-light emitting diodes (LEDs);
a transparent flexible electrode layer formed on the second planarization layer;
a bonding layer formed on the flexible electrode layer; and
a flexible substrate formed on the bonding layer.

21. The system of claim 20, wherein the plurality of circuits comprise a plurality of thin-film transistors (TFTs).

22. The system of claim 20, wherein the transparent flexible electrode layer comprises partially reduced graphene and a metal mesh.

23. The system of claim 22, wherein the metal mesh is comprised of one or more of Aluminum, Copper, Platinum, or Gold.

24. The system of claim 20, wherein the system comprises a foldable display.

25. The system of claim 24, wherein the foldable display is part of a foldable palm-top device.
